(19) United States
(12) Patent Application Publication
(10) Pub. No.: US 2025/0240919 A1
(43) Pub. Date: Jul. 24, 2025

(54) LIQUID COLLECTING DEVICE

(71) Applicant: SHENZHEN ENVICOOL TECHNOLOGY CO., LTD., Shenzhen (CN)

(72) Inventors: Xiaoxin XU, Shenzhen (CN); Xiaolei AI, Shenzhen (CN); Zhen XIONG, Shenzhen (CN); Xiaojin CHENG, Shenzhen (CN)

(73) Assignee: SHENZHEN ENVICOOL TECHNOLOGY CO., LTD., Shenzhen (CN)

(21) Appl. No.: 18/814,638

(22) Filed: Aug. 26, 2024

(30) Foreign Application Priority Data
Jan. 19, 2024 (CN) 202420144179.7

(51) Int. Cl. H05K 7/20

(52) U.S. Cl. CPC H05K 7/20272; H05K 7/20254; H05K 7/20772

(57) ABSTRACT

A liquid collecting device includes a cooling plate and a liquid collecting trough. The liquid collecting trough is arranged surrounding a joint connected to the cooling plate, the liquid collecting trough is provided with a liquid collecting opening, which is provided towards at least part of a pipeline assembly connected to the joint and covers an area where the joint and at least part of the pipeline assembly are located, so that a liquid cooling medium leaking from the at least part of the pipeline assembly as well as a connection position between the joint and the cooling plate can be collected in the liquid collecting trough.

### CROSS REFERENCE TO RELATED APPLICATIONS

This application claims the priority to Chinese Patent Application No. 202420144179.7 titled “LIQUID COLLECTING DEVICE”, filed with the China National Intellectual Property Administration on Jan. 19, 2024, which is incorporated herein by reference in its entirety.

### FIELD

The present disclosure relates to the technical field of cooling-plate liquid cooling, and in particular to a liquid collecting device.

### BACKGROUND

At present, with the development of the cooling technology for the mainboard of server, the cooling-plate liquid cooling technology has become a prevailing cooling technology for servers.

In the conventional technology, the cooling-plate liquid cooling device includes a cooling plate, a liquid guide pipeline, and a joint. The liquid guide pipeline is connected to the cooling plate through the joint, to supply a liquid cooling medium to the cooling plate, so as to realize heat dissipation of the mainboard by contact between the cooling plate and the mainboard or other heating components.

Generally, the joint is a pagoda joint, which is inserted into the liquid guide pipeline via a multi-stage pagoda structure and is sealedly connected with the liquid guide pipeline. Due to inevitable defects in process of production and installation, a risk of leakage still exists. Besides, the liquid guide pipeline also has a risk of leakage, causing a great risk to the hardware and the data security of the server. Currently, a liquid-storage sleeve pipe is generally used to deal with the leakage, that is, the liquid-storage sleeve pipe is sleeved outside the liquid guide pipeline and the joint, to store a leaked liquid in the liquid-storage sleeve pipe in case of leakage.

It is founded in the research of the present disclosure by the inventor that there are at least the following technical problems in the conventional technology.

The installation of the liquid-storage sleeve pipe is cumbersome, and with the direction connection between the liquid-storage sleeve pipe and the joint, leakage is likely occur, where the leaked liquid may flow out of the liquid-storage sleeve pipe, resulting in a poor leakage prevention effect, which cannot meet the leakage prevention requirements of the server. In addition, due to the internal pressure, when the amount of the leaked liquid stored in the liquid-storage sleeve pipe reaches a certain level, there is a risk of leakage in the liquid-storage sleeve pipe.

Therefore, a technical problem to be addressed by those skilled in the art is to provide a liquid collecting device that can collect the leaked liquid from pipelines and their connections at the cooling plate, to meet the leakage prevention requirements of the server.

### SUMMARY

An object of the present disclosure is to provide a liquid collecting device, which can collect the leaked liquid from the pipelines and their connections at the cooling plate to meet the leakage prevention requirements of the server.

In order to achieve the above object, a liquid collecting device is provided in the present disclosure, including a cooling plate and a liquid collecting trough provided surrounding a joint connected to the cooling plate, where the liquid collecting trough is provided with a liquid collecting opening, which faces at least part of a pipeline assembly connected to the joint and corresponds to the joint and the at least part of the pipeline assembly, so that a liquid cooling medium leaking from the at least the part of the pipeline assembly 4 as well as a connection position between the joint and the cooling plate can be collected in the liquid collecting trough.

In some embodiments, the liquid collecting trough and the cooling plate are provided in a split manner, and the liquid collecting trough is located outside the cooling plate.

In some embodiments, the liquid collecting device further includes an enclosing barrier, where the enclosing barrier is arranged to enclose a periphery of the joint, and the enclosing barrier and the cooling plate together form the liquid collecting trough.

In some embodiments, the cooling plate includes a heat-dissipating plate and a cover plate arranged on the heat-dissipating plate, the enclosing barrier is arranged surrounding the cover plate, and a sealing ring is provided between the enclosing barrier and the cover plate to seal a gap therebetween; a mounting groove, having a depth smaller than a thickness of the sealing ring, is provided on an outer wall of the cover plate, and the sealing ring is fitted in the mounting groove.

In some embodiments, the liquid collecting trough is embodied as a collecting tray arranged on the cooling plate, where the collecting tray is provided with a through hole for the joint to pass through; the collecting tray includes a loop-shaped protruding structure that protrudes towards the at least part of the pipeline assembly, to form the liquid collecting trough; and the collecting tray further includes a connecting plate, and the loop-shaped protruding structure is provided on the connecting plate, and the connecting plate is connected to the cooling plate.

In some embodiments, the pipeline assembly includes a liquid guide tube and an anti-leakage outer tube sleeved outside the liquid guide tube, and a leakage detection strip is provided on the inner wall of the anti-leakage outer tube.

In some embodiments, the cooling plate includes a heat-dissipating plate and a cover plate arranged on the heat-dissipating plate, and the liquid collecting trough is a groove provided on the cover plate.

In some embodiments, the liquid collecting device further includes a flow guiding structure, where the flow guiding structure is provided on the joint and cooperates with the at least part of the pipeline assembly, and the flow guiding structure extends into the liquid collecting trough, to guide the liquid cooling medium leaking from the at least part of the pipeline assembly into the liquid collecting trough.

In some embodiments, the liquid collecting device further includes a cover, which is arranged on the liquid collecting trough to prevent the liquid cooling medium from leaking out of the liquid collecting trough.

In some embodiments, the liquid collecting device further includes a suction mechanism connected to the liquid collecting trough and configured to draw the liquid cooling medium out of the liquid collecting trough, where the suction mechanism includes a liquid suction tube, a liquid suction assembly, a leakage detector and a control assembly. One end of the liquid suction tube extends into the liquid collecting trough. The liquid suction assembly is connected to the liquid suction tube to draw the liquid cooling medium out of the liquid collecting trough via the liquid suction tube. The leakage detector is located in the liquid collecting trough and configured detect an amount of liquid cooling medium in the liquid collecting trough. The control assembly is electrically connected to the leakage detector and the liquid suction assembly, to control the liquid suction assembly to be started to draw the liquid cooling medium out of the liquid collecting trough when the amount of liquid cooling medium in the liquid collecting trough exceeds a warning level.

Compared with the conventional technology, the liquid collecting device provided in the embodiments of the present disclosure includes a cooling plate and a liquid collecting trough. Specifically, the liquid collecting trough is arranged surrounding a joint connected to the cooling plate, the liquid collecting trough is provided with a liquid collecting opening, which faces at least part of a pipeline assembly connected to the joint and covers an area where the joint and the at least part of the pipeline assembly are located, so that the liquid cooling medium leaked from the at least part of the pipeline assembly as well as the connection position between the joint and the cooling plate can be collected in the liquid collecting trough.

As can be seen that, on one hand, the liquid collecting opening of the liquid collecting trough can cover the area where the joint connected to the cooling plate and the at least part of the pipeline assembly are located. As such, the liquid cooling medium leaked from the at least part of the pipeline assembly can be collected by the liquid collecting trough, preventing the leaked liquid above the cooling plate from leaking out further. On the other hand, the liquid collecting trough is provided surrounding the joint, in this way, even if there is leakage of liquid cooling medium at the connection position between the joint and the cooling plate, under the action of the internal pressure of the joint and the cooling plate, the leaked liquid cooling medium will eventually enter the liquid collecting trough, ensuring that the leakage of liquid at the position where the cooling plate is located cannot leak out. Therefore, with the liquid collecting device provided in the embodiments of the present disclosure, the liquid leakage, caused by defects of structures and connections, in the pipelines and between the cooling plate and the joint, can be collected, to meet the leakage prevention requirements of the server, thereby improving the safety of server operation.

### BRIEF DESCRIPTION OF THE DRAWINGS

For more clearly illustrating embodiments of the present application or the technical solutions in the conventional technology, drawings referred to describe the embodiments or the conventional technology will be briefly described hereinafter. Apparently, the drawings in the following description are only some examples of the present application, and for those skilled in the art, other drawings may be obtained based on these drawings without any creative efforts.

FIG. 1 is a schematic structural view of a liquid collecting device according to an embodiment of the present disclosure;

FIG. 2 is a top view of the liquid collecting device in FIG. 1;

FIG. 3 is a cross-sectional view of the liquid collecting device in FIG. 1; and

FIG. 4 is a schematic view of the liquid collecting device assembled with a cover according to an embodiment of the present disclosure.

Reference numerals:

| | | | |
|---|---|---|---|
| 1 | cooling plate, | 11 | heat-dissipating plate, |
| 12 | cover plate, | 2 | liquid collecting trough, |
| 21 | liquid collecting opening, | 3 | joint, |
| 31 | flow guiding structure, | 4 | pipeline assembly, |
| 41 | liquid guide tube, | 42 | anti-leakage outer tube, |
| 5 | enclosing barrier, | 6 | cover, |
| 7 | suction mechanism. | | |

### DETAILED DESCRIPTION OF THE EMBODIMENTS

Technical solutions according to the embodiments of the present application will be described clearly and completely as follows in conjunction with the accompany drawings in the embodiments of the present application. It is obvious that the described embodiments are only a part of the embodiments according to the present application, rather than all of the embodiments. All the other embodiments obtained by those skilled in the art based on the embodiments in the present application without any creative work belong to the scope of protection of the present application.

For those skilled in the art to better understand the solution of the present disclosure, the present disclosure is described in detail hereinafter in conjunction with the drawings and specific embodiments.

It should be noted that the orientation terms such as “upper end”, “lower end”, “left side”, and “right side” in this application are defined based on the drawings of the specification.

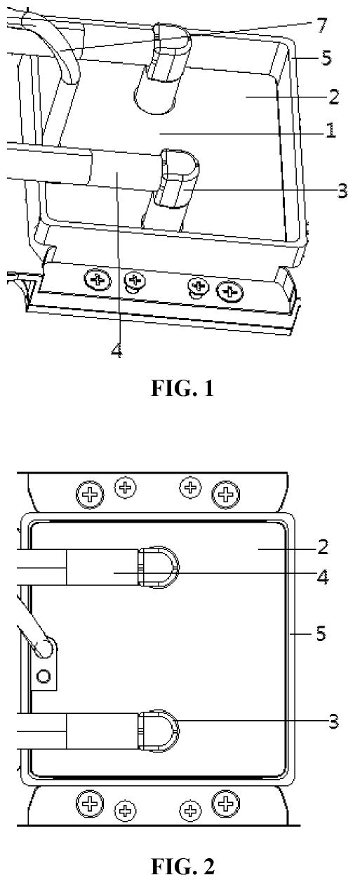

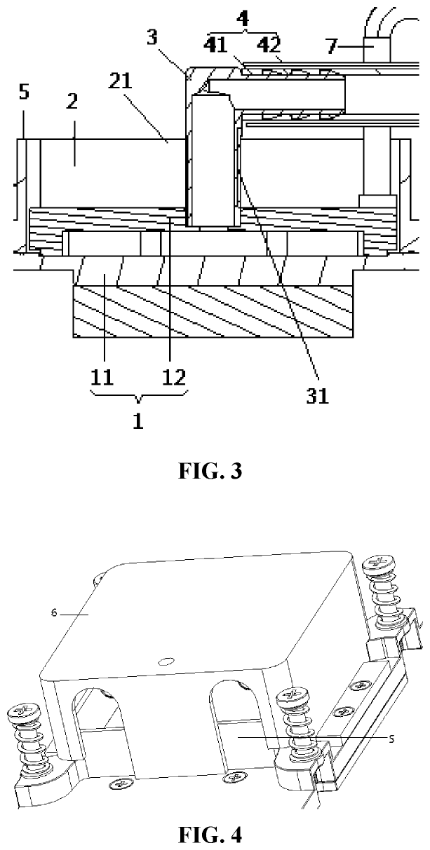

Refer to FIG. 1 to FIG. 4, where FIG. 1 is a schematic view showing the structure of a liquid collecting device according to an embodiment of the present disclosure; FIG. 2 is a top view of the liquid collecting device in FIG. 1; FIG. 3 is a cross-sectional view of the liquid collecting device in FIG. 1; and FIG. 4 is a schematic view showing the liquid collecting device being assembled with a cover according to an embodiment of the present disclosure.

A liquid collecting device according to an embodiment of the present disclosure includes a cooling plate 1. The cooling plate 1 includes a heat-dissipating plate 11 and a cover plate 12. The heat-dissipating plate 11 and the cover plate 12 are connected to form a liquid cooling cavity for accommodating a liquid cooling medium. The heat-dissipating plate 11 is configured to be in contact with components of a server, such as a mainboard, so as to dissipate heat from the mainboard.

The liquid collecting device further includes a liquid collecting trough 2. Specifically, the liquid collecting trough 2 is provided to surround a joint 3 connected to the cooling plate 1. The liquid collecting trough 2 is provided with a liquid collecting opening 21 facing at least part of the pipeline assembly 4 connected to the joint 3. The liquid collecting opening 21 covers, or in other words, corresponds to, an area where the joint 3 and the at least part of the pipeline assembly 4 are located, so that the liquid cooling medium leaking from the at least part of the pipeline assembly 4 as well as a connection position between the joint 3 and the cooling plate 1 can be collected in the liquid collecting trough 2.

The pipeline assembly 4 includes a liquid guide tube 41 and an anti-leakage outer tube 42 sleeved outside the liquid guide tube 41. An accommodation cavity is formed between the anti-leakage outer tube 42 and the liquid guide tube 41 for accommodating the leaked liquid. In addition, a leakage detection strip is further provided on an inner wall of the anti-leakage outer tube 42.

It should be noted that the anti-leakage outer tube 42 may be an one-piece tube that can be directly sleeved onto the liquid guide tube 41, but it's difficult to mount the leakage detection strip in the one-piece tube. In view of this, preferably, the anti-leakage outer tube 42 includes a transparent strip rolled into a tubular-shaped structure and a self-sealing strip that connects two lateral edges of the transparent strip along the extension direction of the transparent strip, so as to constrain the transparent strip into the tubular-shaped structure through the self-sealing strip. Alternatively, the connection between the two lateral edges of the transparent strip may be achieved by other means besides the self-sealing strip mentioned above, such as snap-fitting, adhesive bonding, and so on. It should be noted that, when entering the anti-leakage outer tube 42, the leaked liquid is substantially in a low-pressure state, and thus the strength of the above connection can meet the needs. Alternatively, a non-transparent strip may also be used instead of the transparent strip, but the transparent strip has an advantage in observing.

Preferably, the liquid collecting trough 2 is provided below the at least part of the pipeline assembly 4 connected to the joint 3, which allows the liquid collecting trough 2 to receive the liquid cooling medium leaking from the at least part of the pipeline assembly 4 and to collect the liquid cooling medium leaking from the connection position between the joint 3 and the cooling plate 1.

It should be noted that the liquid cooling medium leaked from the at least part of the pipeline assembly 4 mainly includes two parts, where one part is the liquid cooling medium leaked from a crack of the anti-leakage outer tube 42 (the crack formed due to defects in the structure of the anti-leakage outer tube itself or connection), and this part of the liquid cooling medium directly drips into the liquid collecting trough 2; the other part is the liquid cooling medium leaking from an orifice at an end of the anti-leakages outer tube 42 (such as leakage caused by a defect of connection between the liquid guide tube 41 and the joint 3). Due to a gap between the end of the anti-leakage outer tube 42 and the joint 3, the liquid cooling medium leaking from the orifice at the end of the anti-leakage outer tube 42 can flow into the liquid collecting trough 2 along an outer wall of the joint 3.

As can be seen, on one hand, the liquid collecting opening 21 of the liquid collecting trough 2 can cover the area where the joint 3 connected to the cooling plate 1 and the at least the part of the pipeline assembly 4 are located. In this way, the liquid cooling medium leaked from the at least part of the pipeline assembly 4 can be collected by the liquid collecting trough 2, thereby ensuring that the leaked liquid above the cooling plate 1 cannot leak out. On the other hand, the liquid collecting trough 2 is arranged to surround the joint 3. In this way, even if there is leakage of liquid cooling medium at the connection position between the joint 3 and the cooling plate 1, under the action of the internal pressure of the joint 3 and the cooling plate 1, the leaked liquid cooling medium will eventually enter the liquid collecting trough 2, ensuring that the leakage of liquid at the position where the cooling plate 1 is located cannot leak out.

With this arrangement, the liquid leakage, caused by defects of structures and connections, in the pipelines and between the cooling plate 1 and the joint 3, can be collected, to meet the leakage prevention requirements of the server, thereby improving the safety of server operation.

It can be seen from the above that, in order to facilitate liquid collection, the liquid collecting trough 2 may be arranged outside the cooling plate 1, such as above the cooling plate 1, or can be arranged inside the cooling plate 1, such as inside the cover plate 12 of the cooling plate 1.

In some embodiments, the liquid collecting trough 2 and the cooling plate 1 are provided in a split manner, and the liquid collecting trough 2 is located outside the cooling plate 1.

It can be understood that the liquid collecting trough 2 and the cooling plate 1 being provided in a split manner, that is, a separate structure having the liquid collecting trough 2 may be provided on the cooling plate 1, which does not affect the structure of the cooling plate 1, and the cooling plate 1 can be manufactured separately in batches. Meanwhile, the split manner also has the advantages that, when the liquid collecting trough 2 is damaged or needs to be replaced, it can be directly replaced without disassembling the cooling plate 1, which greatly improves the efficiency of assembly and disassembly.

In this embodiment, the liquid collecting trough 2 may be formed by a liquid collecting structure together with the cooling plate 1, or be formed by an individual liquid collecting structure, which is described hereinafter.

In a case that the liquid collecting trough 2 is formed by the liquid collecting structure together with the cooling plate 1, the liquid collecting device further includes an enclosing barrier 5, which is arranged to enclose the periphery of the joint 3, and the enclosing barrier 5 and the cooling plate 1 together form the liquid collecting trough 2.

Specifically, the enclosing barrier 5 may be arranged surrounding the cover plate 12. Moreover, in order to ensure the sealing performance of the connection between the enclosing barrier 5 and the cover plate 12, a sealing ring is provided between the enclosing barrier 5 and the cover plate 12 to seal a gap therebetween. For example, a mounting groove, having a depth smaller than a thickness of the sealing ring, may be provided on an outer wall of the cover plate 12, and the sealing ring is fitted in the mounting groove. As such, when being fitted, the sealing ring is compressed by its own elasticity, thereby ensuring that the gap between the sealing ring 5 and the cover plate 12 is sealed.

In this case, the cover plate 12 of the cooling plate 1 serves as a bottom face of the liquid collecting trough 2, and the enclosing barrier 5 being of a closed fence structure serves as the side face of the liquid collecting trough 2, thereby forming the liquid collecting trough 2 capable of collecting the leaked liquid.

In the case that the liquid collecting trough 2 is formed by an individual collecting structure, the liquid collecting trough 2 is embodied as a collecting tray arranged on the cooling plate 1. The collecting tray is provided with a through hole for the joint 3 to pass through, and the joint 3 passes through the through hole to be connected to the cooling plate 1. Besides, the collecting tray includes a loop-shaped protruding structure that protrudes towards the at least part of the pipeline assembly 4, to form the liquid collecting trough 2.

Based on the above, the collecting tray further includes a connecting plate, and the loop-shaped protruding structure is provided on the connecting plate, and the connecting plate is connected to the cooling plate 1. The connecting plate and the cooling plate 1 may be connected by a detachable connector (screws or bolts).

In this case, the connecting plate serves as the bottom face of the liquid collecting trough 2, and the loop-shaped protruding structure, being of a closed fence structure, serves as the side face of the liquid collecting trough 2, thereby forming the liquid collecting trough 2 capable of collecting the leaked liquid.

In some embodiments, the liquid collecting trough 2 and the cooling plate 1 are of an integrated structure, and the liquid collecting trough 2 is located inside the cooling plate 1.

Specifically, the cooling plate 1 includes a heat-dissipating plate 11 and a cover plate 12 arranged on the heat-dissipating plate 11. The cover plate 12 is provided with a recessed area or a groove, which is recessed in a direction away from the at least part of the pipeline assembly 4. As such, the liquid collecting trough 2 may be embodied as the groove provided on the cover plate 12. The gap between the joint 3 and the cooling plate 1 is in communication with the groove, allowing the liquid cooling medium leaked from the gap between the joint 3 and the cooling plate 1 to flow into the groove, which ensures that no leaked liquid is flowed out to affect the safe operation of the components of the server.

In order to facilitate the guiding of the liquid cooling medium leaked through the orifice at the end of the anti-leakage outer tube 42, the liquid collecting device further includes a flow guiding structure 31. The flow guiding structure 31 is provided on the joint 3 and cooperates with the at least part of the pipeline assembly 4 (in the case that the pipeline assembly 4 is provided on one single side of the joint 3, the flow guiding structure 31 and the pipeline assembly 4 are located on the same side of the joint 3). The flow guiding structure 31 extends into the liquid collecting trough 2, so that the leaked liquid flowing out of the orifice at the end of the anti-leakage outer tube 42 is guided into the liquid collecting trough 2 by the flow guiding structure 31.

It can be understood that, due to the gap between the end of the anti-leakage outer tube 42 and the joint 3, the liquid cooling medium leaked through the orifice at the end of the anti-leakage outer tube 42 can flow to the liquid collecting trough 2 along the outer wall of the joint 3. As such, the flow guiding structure 31 is provided on the outer wall of the joint 3, the flow guiding structure 31 may be a guide groove. The guide groove may be of a straight or curved structure, provided that it can ensure that the leaked liquid flowing out through the orifice at the end of the anti-leakage outer tube 42 is guided into the liquid collecting trough 2.

In order to prevent the leaked liquid from leaking out of the liquid collecting trough 2, the liquid collecting device further includes a cover 6, which is arranged on the liquid collecting trough 2 to prevent the liquid cooling medium from leaking out of the liquid collecting trough 2.

The outer cover 6 is arranged on the liquid collecting trough 2 by a detachable connector (screws, bolts, etc.), and can cover the liquid collecting opening 21, to prevent the liquid cooling medium from leaking out of the liquid collecting trough 2 via the liquid collecting opening 21.

In an embodiment, the cover 6 is provided with a slotted hole for the pipeline assembly 4 to pass through, so as to facilitate connection between the pipeline assembly 4 and the cooling plate 1.

In order to further meet the leakage prevention requirements of the server, the liquid collecting device further includes a suction mechanism 7, which is connected to the liquid collecting trough 2. The suction mechanism 7 is used to draw the liquid cooling medium out of the liquid collecting trough 2 and gather it into the liquid collecting structure outside the cooling plate 1 to prevent the liquid cooling medium in the liquid collecting trough 2 from exceeding a warning level.

Specifically, the suction mechanism 7 includes a liquid suction tube, a liquid suction assembly, a leakage detector, and a control assembly. One end of the liquid suction tube extends into the liquid collecting trough 2, and the liquid suction assembly is connected to the liquid suction tube. The liquid suction assembly draws the liquid cooling medium out of the liquid collecting trough 2 via the liquid suction tube. The leakage detector is located in the liquid collecting trough 2 for detecting the amount of liquid cooling medium in the liquid collecting trough 2. The control assembly is electrically connected to the leakage detector and the liquid suction assembly. The control assembly is used to control the liquid suction assembly to be started to draw the liquid cooling medium in the liquid collecting trough 2 to the liquid collecting structure outside the cooling plate 1 when the amount of liquid cooling medium in the liquid collecting trough 2 exceeds the warning level.

That is, with the suction mechanism 7, the liquid cooling medium can be drawn out of the liquid collecting trough 2 when the amount of liquid cooling medium in the liquid collecting trough 2 reaches a certain level, which protects the server.

In some embodiments, the leakage detector may be a leakage detection sensor and may be of a sheet-like structure. The sheet-like leakage detector wholly covers the bottom face of the liquid collecting trough 2. In this way, regardless of where the liquid cooling medium is found in the liquid collecting trough 2, the leakage detector can instantly detect the liquid cooling medium and feedback the detected data to the control assembly.

It should be noted that in the present disclosure, the terms such as first and second are only used for distinguishing between similar parts and are not intended to describe a specific sequence or precedence order.

The liquid collecting device according to the present disclosure is described in detail hereinbefore. The principle and the embodiments of the present disclosure are illustrated herein by specific examples. The above description of examples is only intended to help the understanding of the method and the idea of the present disclosure. It should be noted that, for those skilled in the art, a few of modifications and improvements may be made to the present application without departing from the principle of the present application, and these modifications and improvements are also deemed to fall into the scope of the present disclosure defined by the claims.

1. A liquid collecting device, comprising a cooling plate, and a liquid collecting trough provided surrounding a joint connected to the cooling plate, wherein
the liquid collecting trough is provided with a liquid collecting opening, which faces at least part of a pipeline assembly connected to the joint and corresponds to an area where the joint and the at least part of the pipeline assembly, to allow a liquid cooling medium leaking from the at least part of the pipeline assembly as well as a connection position between the joint and the cooling plate to be collected in the liquid collecting trough.

2. The liquid collecting device according to claim 1, wherein the liquid collecting trough and the cooling plate are provided in a split manner, and the liquid collecting trough is located outside the cooling plate.

3. The liquid collecting device according to claim 2, further comprising an enclosing barrier, wherein the enclosing barrier is arranged to enclose a periphery of the joint, and the enclosing barrier and the cooling plate together form the liquid collecting trough.

4. The liquid collecting device according to claim 3, wherein the cooling plate comprises a heat-dissipating plate and a cover plate arranged on the heat-dissipating plate, the enclosing barrier is arranged surrounding the cover plate, and a sealing ring is provided between the enclosing barrier and the cover plate to seal a gap therebetween; and
a mounting groove, having a depth smaller than a thickness of the sealing ring, is provided on an outer wall of the cover plate, and the sealing ring is fitted in the mounting groove.

5. The liquid collecting device according to claim 2, the liquid collecting trough is embodied as a collecting tray arranged on the cooling plate, wherein
the collecting tray is provided with a through hole for the joint to pass through;
the collecting tray comprises a loop-shaped protruding structure that protrudes towards the at least part of the pipeline assembly, to form the liquid collecting trough; and
the collecting tray further comprises a connecting plate, the loop-shaped protruding structure is provided on the connecting plate, and the connecting plate is connected to the cooling plate.

6. The liquid collecting device according to claim 1, wherein the pipeline assembly comprises a liquid guide tube and an anti-leakage outer tube sleeved outside the liquid guide tube, and a leakage detection strip is provided on an inner wall of the anti-leakage outer tube.

7. The liquid collecting device according to claim 1, wherein the cooling plate comprises a heat-dissipating plate and a cover plate arranged on the heat-dissipating plate, and the liquid collecting trough is a groove provided on the cover plate.

8. The liquid collecting device according to claim 1, further comprising a flow guiding structure, wherein
the flow guiding structure is configured to be provided on the joint and cooperate with the at least part of the pipeline assembly; and
the flow guiding structure extends into the liquid collecting trough, to guide the liquid cooling medium leaking from the at least part of the pipeline assembly into the liquid collecting trough.

9. The liquid collecting device according to claim 1, further comprising a cover, which is arranged on the liquid collecting trough to prevent the liquid cooling medium from leaking out of the liquid collecting trough.

10. The liquid collecting device according to claim 1, further comprising a suction mechanism connected to the liquid collecting trough and configured to draw the liquid cooling medium out of the liquid collecting trough, wherein the suction mechanism comprises:
a liquid suction tube with one end extending into the liquid collecting trough;
a liquid suction assembly, which is connected to the liquid suction tube to draw the liquid cooling medium out of the liquid collecting trough via the liquid suction tube;
a leakage detector, which is located in the liquid collecting trough and configured to detect an amount of liquid cooling medium in the liquid collecting trough; and
a control assembly, which is electrically connected to the leakage detector and the liquid suction assembly, to control the liquid suction assembly to be started to draw the liquid cooling medium out of the liquid collecting trough when the amount of liquid cooling medium in the liquid collecting trough exceeds a warning level.
